(19) United States
(12) Patent Application Publication
(10) Pub. No.: US 2013/0044439 A1
(43) Pub. Date: Feb. 21, 2013

(54) MOUNTING APPARATUS FOR BLUETOOTH COMPONENT

(71) Applicants: XUE-JIAO GUO, Wuhan City (CN); HENG TAO, Wuhan City (CN); SHU-QIU WANG, Wuhan City (CN)

(72) Inventors: XUE-JIAO GUO, Wuhan City (CN); HENG TAO, Wuhan City (CN); SHU-QIU WANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/525,516

(22) Filed: Jun. 18, 2012

(30) Foreign Application Priority Data
Aug. 18, 2011 (CN) 201110237572.8

(51) Int. Cl. H05K 7/00

(52) U.S. Cl. 361/747

(57) ABSTRACT

A mounting apparatus includes an enclosure and a securing member. The enclosure includes a plate. The securing member is secured to an outer surface of the plate. The securing member includes a base board and a locking portion located on the base board. The locking portion is configured to secure a bluetooth component to the base board. The locking portion is located between the base board and the outer surface of the plate.

### BACKGROUND

1. Technical Field

The present disclosure relates to mounting apparatuses, and particularly to a mounting apparatus for a bluetooth component.

2. Description of Related Art

A bluetooth component can be provided in a computer system to communicate with a wireless keyboard, or a wireless mouse, etc. The bluetooth component needs to be mounted on a bracket, which secures the bluetooth component to inside of an enclosure. The bracket can be secured to the enclosure by screws, which is time-consuming and laborious. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus and a bluetooth component in accordance with an embodiment.

FIG. 2 is similar to FIG. 1, but viewed in a different aspect.

FIG. 3 is an enlarged view of a circled portion III of FIG. 2.

FIG. 4 is an isometric view of an assembly of a securing member and a bluetooth component of FIG. 1.

FIG. 5 is similar to FIG. 2, but shows the securing member and the bluetooth component secured to an enclosure.

FIG. 6 is an isometric view of an assembly of the mounting apparatus and the bluetooth component of FIG. 2.

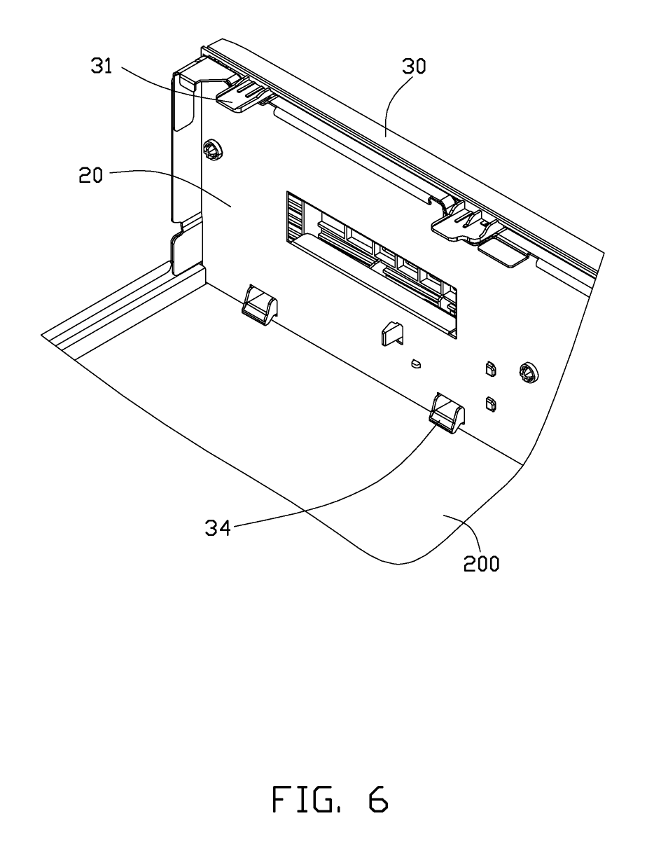

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

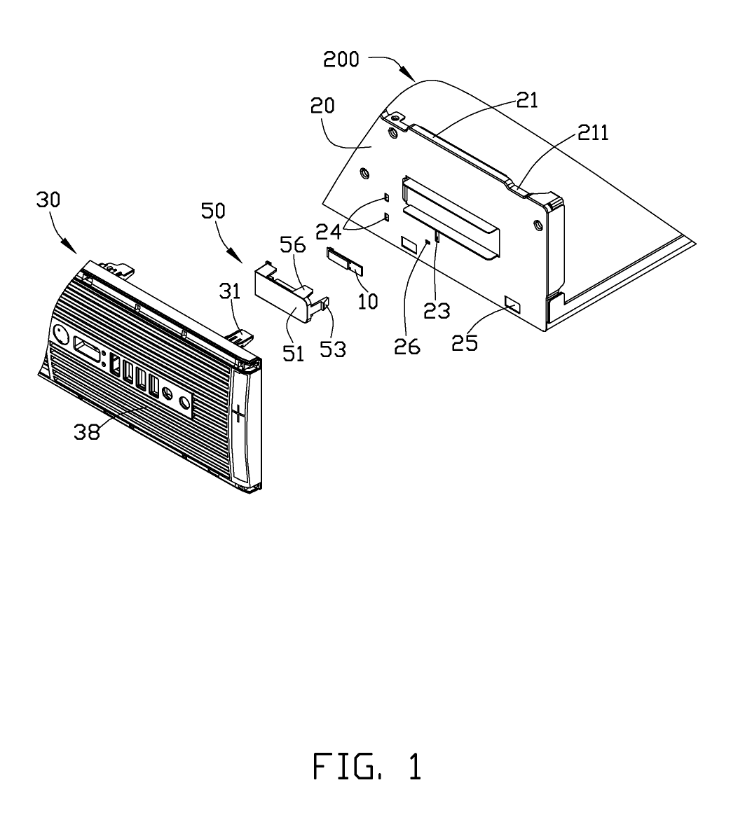

Referring to FIG. 1, a mounting apparatus in accordance with an embodiment includes an enclosure 200 and a securing member 50. The securing member 50 is configured to secure a bluetooth component 10 to the enclosure 200. In one embodiment, the enclosure 200 is a computer enclosure, the bluetooth component 10 is configured to electrically connect to a motherboard in the computer enclosure, and the bluetooth component 10 is configured to transmit and receive bluetooth signals between a computer and a peripheral device, such as a keyboard or a mouse.

The enclosure 200 includes a plate 20. The plate 20 defines a first securing hole 23, two second securing holes 24, and a third securing hole 26. The third securing hole 26 is located between the two second securing holes 24 and the first securing hole 23. The plate 20 further defines two locking holes 25. A flange 21 extends inward from a top edge of the plate 20. A recess 211 is defined in the flange 21.

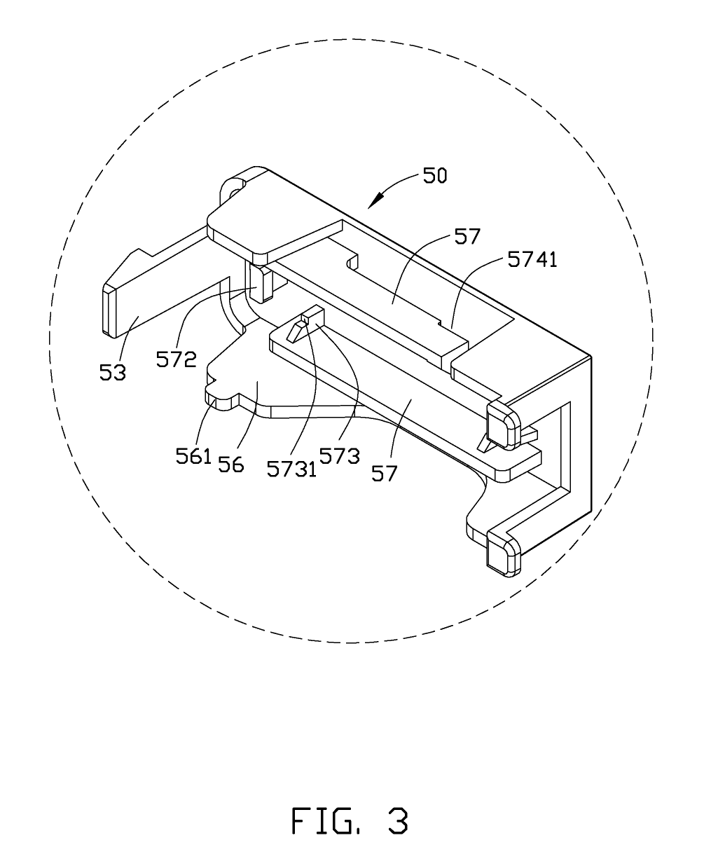

Referring to FIGS. 1-3, the securing member 50 includes a base board 51 and four positioning boards 56 substantially parallel to each other. A first and a second of the four positioning boards 56 are located on a bottom edge of the base board 51, and a third and a fourth of the four positioning boards 56 are located on a top edge of the base board 51. A tab 561 extends from the first of the four positioning boards 56. A first hook 53 is located on a left edge of the base board 51, and two second hooks 54 are located on a right edge of the base board 51. The first hook 53 is resilient and deformable, and the two second hooks 54 are connected to the third and a fourth of the four positioning boards 56. A cutout 58 is defined between the two second hooks 54. A locking portion 57 is located on the base board 51 between the first and fourth of the four positioning boards 56 and the second and third of the four positioning boards 56 and between the first hook 53 and the second hooks 54. The locking portion 57 includes two walls 571 substantially parallel to the four positioning boards 56. Two positioning blocks 573 are located on each of the two walls 571, and the four positioning blocks 573 are substantially perpendicular to the two walls 571. A first and a second of the four positioning blocks 573 are adjacent the first hook 53, and a third and fourth of the four positioning blocks 573 are adjacent the second hooks 54. Each positioning block 573 defines a supporting surface 5731. A limiting block 574 is located between two positioning blocks 573 of one of the two walls 571. A gap 5741 is defined between the limiting block 574 and an inner surface of the base board 57. A restricting portion 572 is located on the inner surface of the base board 57 between the two walls 571.

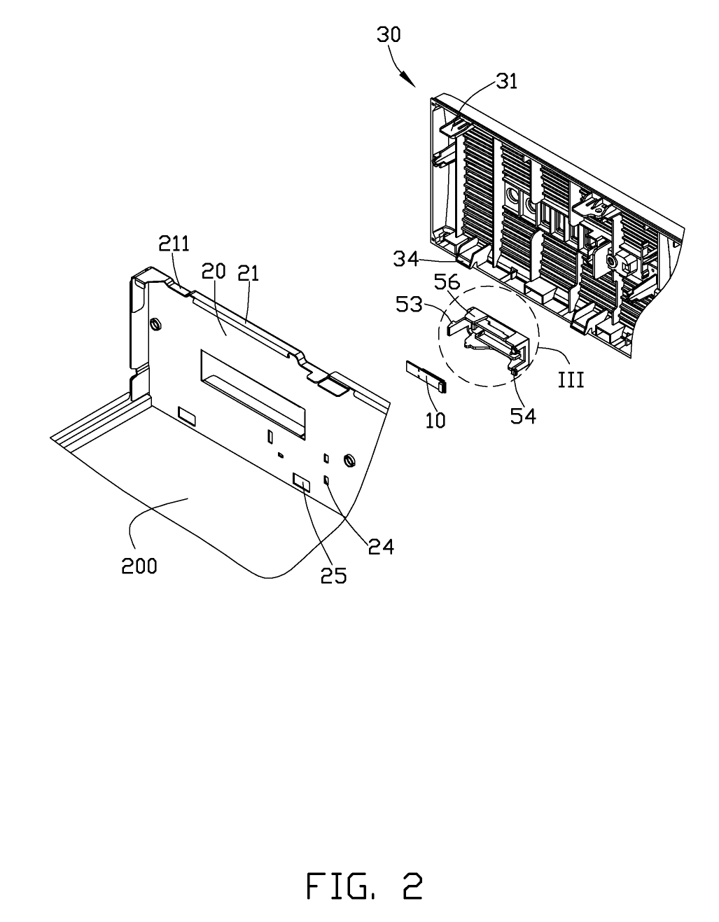

Referring to FIG. 2, in assembly, the bluetooth component 10 is placed on the supporting surface 5731 of the third and the fourth of the four positioning blocks 573 and in the cutout 58 between the two second hooks 54 and between two of the four positioning blocks 573. An end of the bluetooth component 10 is aligned with the gap 5741. The bluetooth component 10 is inserted from right to left through the gap 5741, until an inner face of the bluetooth component 10 is blocked by the restricting block 572. The bluetooth component 10 is then located on the supporting surface 5731 of the first and the second of positioning blocks 573. The bluetooth component 10 is positioned between the first and second and between the third and the fourth of the four positioning blocks 573. Therefore, the four positioning blocks 573 prevent the bluetooth component 10 from moving in a vertical direction, and the restricting block 572 and the limiting block 574 prevent the bluetooth component 10 from moving in a horizontal direction, which is substantially perpendicular to the base board 57. Thereby, the bluetooth component 10 is wholly secured in the securing member 50.

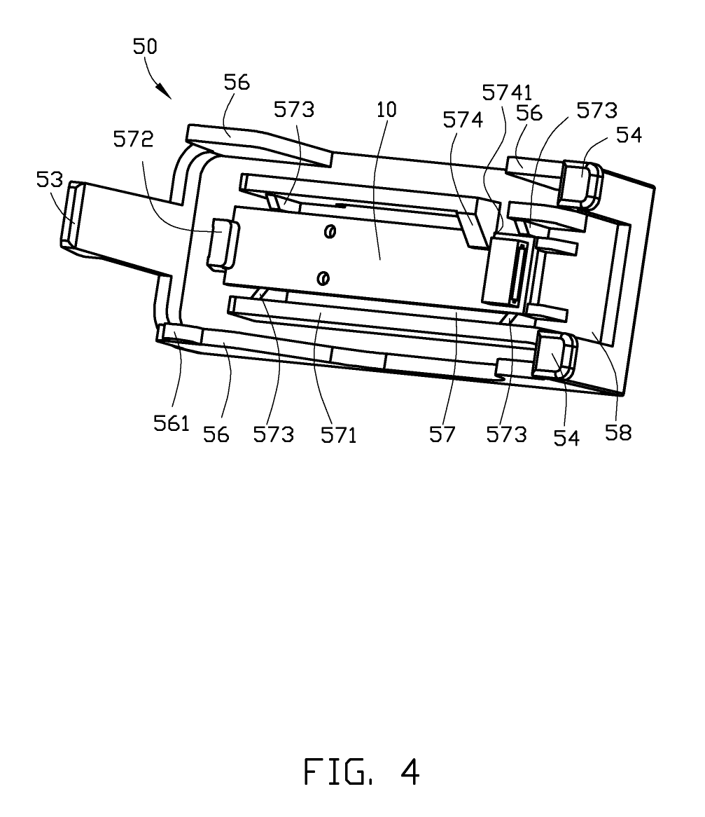

Referring also to FIG. 4, the bluetooth component 10 and the securing member 50 are assembled by being placed on an outer surface of the plate 20. The inner surface of the bluetooth component 10 faces the outer surface of the plate 20. The two second hooks 54 are inserted into the two second securing holes 24. The assembly is then rotated between the two hooks 54 and the two second securing holes 24. The first hook 53 is elastically deformed to be inserted through the first securing hole 23. When the four positioning blocks 56 abuts the outer surface of the plate 20, the first hook 53 snaps back to engage in the first securing hole 23, and the tab 561 is engaged in the third securing hole 26. Thereby, the bluetooth component 10 and the securing member 50 are assembled and secured to the plate 20.

In disassembly, the first hook 53 is elastically deformed from the inside of the enclosure 200 to disengage from the first securing hole 23. The bluetooth component 10 and the securing member 50 are rotated as an assembly away from the plate 20. The tab 561 is disengaged from the third securing hole 26. The two second hooks 54 can then be disengaged from the two second securing holes 24.

Referring also to FIG. 1, the mounting apparatus further comprises a bezel 30. The bezel 30 defines a plurality of ventilation holes 38. A first latch portion 31 and two second latch portions 34 are located on the bezel 30.

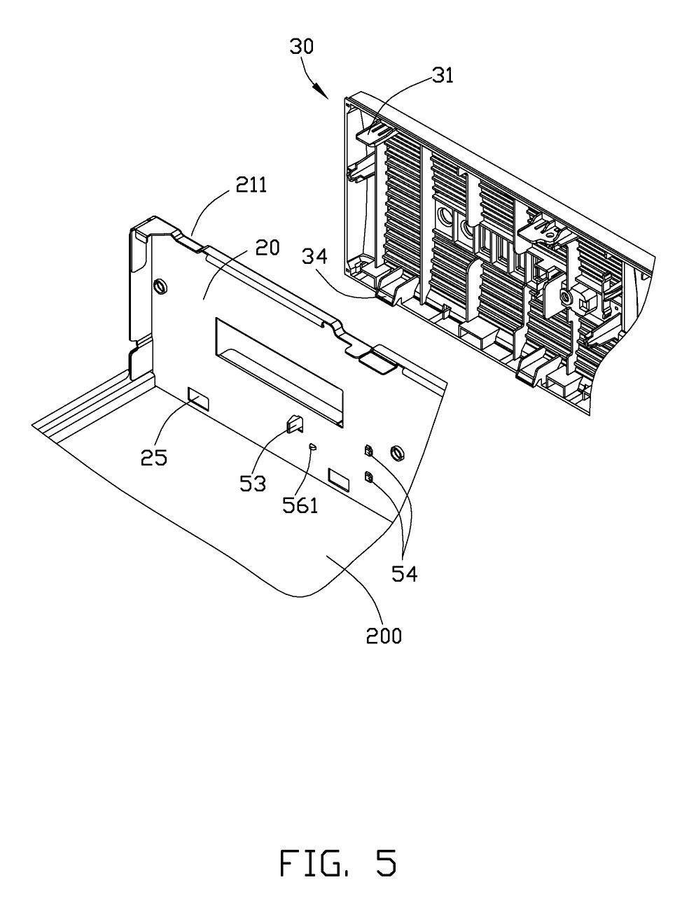

Referring to FIG. 5, in assembling the bezel 30 to the plate 20, the first latch portion 31 is engaged in the recess 211 of the plate 20. The two second latch portions 34 are engaged in the two locking holes 25 of the plate 20. Thereby, the bezel 30 is secured to the plate 20. The bluetooth component 10 cannot be seen from outside of the bezel 30 via the ventilation holes 38, because the bluetooth component 10 is shielded by the securing member 50.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus for a bluetooth component, comprising:
an enclosure comprising a plate; and
a securing member secured to an outer surface of the plate, the securing member comprising a base board and a locking portion located on the base board, wherein the locking portion secures the bluetooth component to the base board, and the locking portion is located between the base board and the outer surface of the plate.

2. The mounting apparatus of claim 1, wherein the locking portion comprises two walls substantially parallel to each other, and the two walls receive the bluetooth component therebetween.

3. The mounting apparatus of claim 2, wherein the locking portion further comprises two positioning blocks located on the two walls for sandwiching the bluetooth component therebetween.

4. The mounting apparatus of claim 2, wherein the locking portion further comprises a limiting block located on one of the two walls, and a gap is defined between an inner surface of the base board and the limiting block for receiving the bluetooth component therein.

5. The mounting apparatus of claim 2, wherein the locking portion further comprises a restricting block located between the two walls.

6. The mounting apparatus of claim 1, wherein the securing member further comprises two positioning boards located on the base board, and the two positioning boards abuts on the outer surface of the plate.

7. The mounting apparatus of claim 6, wherein the securing member further comprises a plurality of hooks located on the base board, a plurality of securing holes are defined in the plate, and the plurality of hooks are engaged in the plurality of securing holes to secure the securing member to the plate.

8. A mounting apparatus for a bluetooth component, comprising:
a plate;
a securing member secured to an outer surface of the plate and comprising a base board and a locking portion located on the base board; and
a bezel secured to the plate;
wherein the locking portion secures the bluetooth component to the base board, the locking portion is located between the base board and the outer surface of the plate, and the securing member is located between the bezel and the plate.

9. The mounting apparatus of claim 8, wherein the locking portion comprises two walls substantially parallel to each other, and the two walls receive the bluetooth component therebetween.

10. The mounting apparatus of claim 9, wherein the locking portion further comprises two positioning blocks located on the two walls for sandwiching the bluetooth component therebetween.

11. The mounting apparatus of claim 9, wherein the locking portion further comprises a limiting block located on one of the two walls, a gap is defined between an inner surface of the base board and the limiting block for receiving the bluetooth component therein.

12. The mounting apparatus of claim 9, wherein the locking portion further comprises a restricting block located between the two walls.

13. The mounting apparatus of claim 8, wherein the securing member further comprises two positioning boards located on the base board, and the two positioning boards abuts on the outer surface of the plate.

14. The mounting apparatus of claim 13, wherein the securing member further comprises a plurality of hooks located on the base board, a plurality of securing holes are defined in the plate, and the plurality of hooks are engaged in the plurality of securing holes to secure the securing member to the plate.

15. A mounting apparatus assembly, comprising:
a plate;
a bluetooth component;
a securing member secured to an outer surface of the plate and comprising a base board and a locking portion located on the base board; and
a bezel secured to the plate;
wherein the locking portion secures the bluetooth component to the base board, the locking portion is located between the base board and the outer surface of the plate, and the securing member is located between the bezel and the plate.

16. The mounting apparatus assembly of claim 15, wherein the locking portion comprises two walls substantially parallel to each other, and the bluetooth component is received between the two walls.

17. The mounting apparatus assembly of claim 16, wherein the locking portion further comprises two positioning blocks located on the two walls, and the bluetooth component is sandwiched between the two positioning blocks to prevent the bluetooth component from moving in a first direction substantially perpendicular to the two walls.

18. The mounting apparatus assembly of claim 17, wherein the locking portion further comprises a limiting block is located on one of the two walls, a gap is defined between an inner surface of the base board and the limiting block, and the bluetooth component is received in the gap to prevent the bluetooth component from moving in a second direction substantially perpendicular to the first direction.

19. The mounting apparatus assembly of claim 17, wherein the locking portion further comprises a restricting block located between the two walls, and the restricting block engages with the bluetooth component to prevent the bluetooth component from moving in a second direction substantially perpendicular to the first direction.

20. The mounting apparatus assembly of claim 15, wherein the securing member further comprises two positioning boards located on the base board, the two positioning boards abut on the outer surface of the plate, the securing member further comprises a plurality of hooks located on the base board, a plurality of securing holes are defined in the plate, and the plurality of hooks are engaged in the plurality of securing holes to secure the securing member to the plate.
